(19) United States
(12) Patent Application Publication
(10) Pub. No.: US 2013/0229214 A1
(43) Pub. Date: Sep. 5, 2013

(54) SEMICONDUCTOR DEVICE GENERATING PHASE-CONTROLLED CLOCK SIGNAL

(71) Applicant: ELPIDA MEMORY, INC., Tokyo (JP)

(72) Inventor: Hideyuki ICHIDA, Tokyo (JP)

(73) Assignee: ELPIDA MEMORY, INC., Tokyo (JP)

(21) Appl. No.: 13/784,283

(22) Filed: Mar. 4, 2013

(30) Foreign Application Priority Data
Mar. 5, 2012 (JP) 2012-047955

(51) Int. Cl. H03L 7/081

(52) U.S. Cl. CPC H03L 7/081
USPC 327/158; 327/156

(57) ABSTRACT

The semiconductor device includes a frequency detection circuit that outputs a frequency detection signal based on a frequency of a first clock signal; a phase comparison circuit that compares a phase of the first clock signal with a phase of a reference clock signal and outputs a phase comparison signal according to a result of the comparison; and a phase adjustment circuit that outputs a second clock signal by shifting the phase of the first clock signal according to the phase comparison signal. An amount of the phase of the first clock signal according to the phase comparison signal is variable according to the frequency detection signal.

### BACKGROUND OF THE INVENTION

1. Field of the Invention

The present invention relates to a semiconductor device, and more particularly relates to a semiconductor device including a clock generation circuit that generates a phase-adjusted clock signal. The present invention also relates to a phase adjustment method of a clock signal in the semiconductor device.

2. Description of Related Art

Most semiconductor devices operate in synchronism with an external clock signal. However, in case the external clock signal is used as a timing signal inside the semiconductor devices, it causes shifting of an operation timing due to a signal delay caused by a wire load. Therefore, the external clock signal is not used as it is inmost semiconductor devices, and an internal clock signal is generated of which the phase is adjusted with respect to the external clock signal and the internal clock signal is used as the timing signal. A circuit that generates such an internal clock signal is referred to as “clock generation circuit”, and as a representative clock generation circuit, a DLL (Delay Locked Loop) circuit has been widely known.

The DLL circuit is a clock generation circuit that is mainly used in a DRAM (Dynamic Random Access Memory), which is used for accurately synchronizing output timings of read data and a data strobe signal with the external clock signal. As an example of the DLL circuit, a DLL circuit that employs a coarse variable delay circuit and a fine variable delay circuit is disclosed in Japanese Patent Application Laid-open No. 2000-122750. The DLL circuit described in Japanese Patent Application Laid-open No. 2000-122750 performs a coarse phase adjustment first by using the coarse variable delay circuit and then performs a fine phase adjustment by using the fine variable delay circuit.

However, in some semiconductor devices, the frequency of the external clock signal is not fixed but arbitrarily selectable within a predetermined range. In such semiconductor devices, the characteristic needed for the DLL circuit varies according to the actually used frequency of the external clock signal, and therefore using the DLL circuit described in Japanese Patent Application Laid-open No. 2000-122750 is not always appropriate. This kind of problem occurs not only in the DLL circuit but also in any semiconductor devices including a clock generation circuit of this kind.

### SUMMARY

In one embodiment of the present invention, there is provided a semiconductor device that includes: a frequency detection circuit outputting a frequency detection signal based on a frequency of a first clock signal; a phase comparison circuit comparing a phase of the first clock signal with a phase of a reference clock signal to generate a phase comparison signal; and a phase adjustment circuit outputting a second clock signal by shifting the phase of the first clock signal based on the phase comparison signal, an amount of shifting the phase of the first clock signal being variable according to the frequency detection signal.

In another embodiment of the present invention, there is provided a method of adjusting a phase of a clock signal, the method including: detecting a frequency of a first clock signal or a second clock signal; generating the second clock signal based on the first clock signal by performing a plurality of phase adjusting operations; and changing a phase adjustment pitch in each of the phase adjusting operations based on the detected frequency.

In still another embodiment of the present invention, there is provided a semiconductor device that includes: a delay circuit configured to receive a first clock signal to generate a second clock signal; a detection circuit configured to detect a frequency of the first clock signal to generate a detection signal; and a control circuit configured to be supplied with the detection signal, to control the delay circuit to shift one of rising and falling edges of the first clock signal at first intervals when the detection signal takes a first value, and to control the delay circuit to shift the one of rising and falling edges of the first clock signal at second intervals when the detection signal takes a second value different from the first value, the first intervals being different from the second intervals.

According to the present invention, a phase adjustment pitch is changed corresponding to the frequency of a clock signal, and therefore it is possible to perform an optimum phase adjustment operation regardless of the actually used frequency of the clock signal.

### BRIEF DESCRIPTION OF THE DRAWINGS

FIG. 1 is a block diagram of a semiconductor device according to an embodiment of the present invention;

FIG. 2 is a block diagram of a frequency detection circuit shown in FIG. 1;

FIG. 3 is a block diagram of a pulse generation circuit shown in FIG. 2;

FIG. 4 is a block diagram of a DLL circuit shown in FIG. 1;

FIG. 5 is a circuit diagram of a part of coarse delay line shown in FIG. 4;

FIG. 6 is a waveform chart showing the operation of the coarse delay line;

FIG. 7 is a circuit diagram of a fine delay line shown in FIG. 4;

FIG. 8 is a circuit diagram of a counter circuit shown in FIG. 4;

FIG. 9 is a schematic view for explaining the operation of a code generation circuit shown in FIG. 4;

FIG. 10 is a timing chart showing the operation of the DLL circuit in case frequency detection signal SELa is activated;

FIG. 11 is a timing chart showing the operation of the DLL circuit in case frequency detection signal SELb is activated;

FIG. 12 is a block diagram where the elements of the semiconductor device are distributed to a plurality of semiconductor chips; and

FIG. 13 is a diagram for explaining of changing the number of valid bits of the counter circuit based on the frequency of the internal clock signal.

### DETAILED DESCRIPTION OF THE EMBODIMENTS

A semiconductor device including a clock generation circuit that performs a phase adjustment of a clock signal is used in various systems. However, the operation condition of the semiconductor device is not always the same, but may be different for each system. One of the operation conditions is the operation frequency defined by a system clock signal. As disclosed in Japanese Patent Application Laid-open No. 2000-122750, the clock generation circuit obtains an internal clock signal having a desired phase by performing a phase adjusting step in a repeated manner within a predetermined period, and therefore it suffices to design an optimum phase adjustment pitch based on the frequency of the system clock signal in such a manner that the phase adjustment operation is correctly completed within the predetermined period when the frequency of the system clock signal is determined in advance.

However, if the frequency of the system clock signal is not determined in advance but the actual frequency differs according to the system condition, the optimum phase adjustment pitch also differs corresponding to the actually used frequency. Specifically, when the actually used frequency of the system clock signal is high (the cycle is short), the phase adjustment pitch needs to be set to a small value. This is because, when the frequency of the system clock signal is high, it is not possible to correctly perform the phase adjustment operation unless the phase adjustment pitch is set to a small value. On the contrary, when the actually used frequency of the system clock signal is low (the cycle is long), the phase adjustment pitch can be set to a large value. This is because, when the frequency of the system clock signal is low, the required accuracy of the phase adjustment is not high. Taking these features into consideration, when the frequency differs according to the system condition, it is necessary to set the phase adjustment pitch to a small value corresponding to the highest frequency of the system clock signal.

In this manner, when the phase adjustment pitch is set to a small enough value, the phase adjustment operation can be correctly performed regardless of the frequency of the system clock signal. However, the inventors of the present invention have found a problem that it takes a long time to complete the phase adjustment operation with a small phase adjustment pitch when the actually used frequency of the system clock signal is low. To deal with this problem, the present invention detects the operation frequency of the system and changes the phase adjustment pitch corresponding to the detected operation frequency.

Preferred embodiments of the present invention will be explained below in detail with reference to the accompanying drawings.

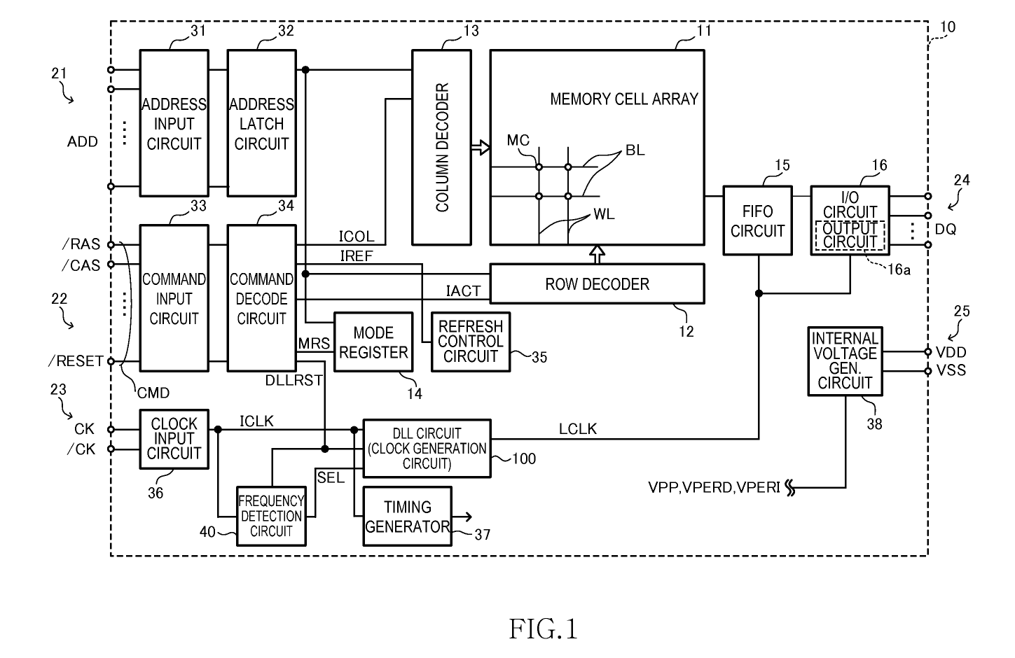

Referring now to FIG. 1, the semiconductor device 10 according to an embodiment of the present invention is a DRAM integrated in a single semiconductor chip. The semiconductor device 10 includes a memory cell array 11. The memory cell array 11 includes a plurality of word lines WL, a plurality of bit lines BL, and a plurality of memory cells MC arranged at their intersections. The selection of the word line WL is performed by a row decoder 12 and the selection of the bit line BL is performed by a column decoder 13.

As shown in FIG. 1, the semiconductor device 10 employs a plurality of external terminals that include address terminals 21, command terminals 22, clock terminals 23, data terminals 24, and power supply terminals 25.

The address terminals 21 are supplied with an address signal ADD from outside. The address signal ADD supplied to the address terminals 21 is transferred via an address input circuit 31 to an address latch circuit 32 that latches the address signal ADD. The address signal ADD latched in the address latch circuit 32 is supplied to the row decoder 12, the column decoder 13, or a mode register 14. The mode register 14 is a circuit in which parameters indicating an operation mode of the semiconductor device 10 are set.

The command terminals 22 are supplied with a command signal CMD from outside. The command signal CMD is constituted by a plurality of signals such as a row-address strobe signal /RAS, a column-address strobe signal /CAS, and a reset signal /RESET. The slash “/” attached to the head of a signal name indicates an inverted signal of a corresponding signal or indicates that the corresponding signal is a low-active signal. The command signal CMD supplied to the command terminal 22 is transferred via a command input circuit 33 to a command decode circuit 34. The command decode circuit 34 decodes the command signal CMD to generate various internal commands that include an active signal IACT, a column signal ICOL, a refresh signal IREF, a mode register set signal MRS, and a DLL reset signal DLLRST.

The active signal IACT is activated when the command signal CMD indicates a row access (an active command). When the active signal IACT is activated, the address signal ADD latched in the address latch circuit 32 is supplied to the row decoder 12. The word line WL designated by this address signal ADD is selected accordingly.

The column signal ICOL is activated when the command signal CMD indicates a column access (a read command or a write command). When the column signal ICOL is activated, the address signal ADD latched in the address latch circuit 32 is supplied to the column decoder 13. In this manner, the bit line BL designated by this address signal ADD is selected accordingly.

Accordingly, when the active command and the read command are issued in this order and a row address and a column address are supplied in synchronism with these commands, read data is read from a memory cell MC designated by these row address and column address. Read data DQ is output to outside from the data terminals 24 via an FIFO circuit 15 and an input/output circuit 16. Meanwhile, when the active command and the write command are issued in this order, a row address and a column address are supplied in synchronism with these commands, and then write data DQ is supplied to the data terminals 24, the write data DQ is supplied via the input/output circuit 16 and the FIFO circuit 15 to the memory cell array 11 and written in the memory cell MC designated by these row address and column address. The FIFO circuit 15 and the input/output circuit 16 are operated in synchronism with an internal clock signal LCLK. The internal clock signal LCLK is generated by a DLL circuit 100 to be explained later. Particularly, the input/output circuit 16 includes an output circuit 16a that outputs the read data DQ. The read data DQ is output from the output circuit 16a to the data terminals in synchronism with the internal clock signal LCLK accordingly.

The refresh signal IREF is activated when the command signal CMD indicates a refresh command. When the refresh signal IREF is activated, a row access is made by a refresh control circuit 35 and a predetermined word line WL is selected. In this manner, a plurality of memory cells MC connected to the selected word line WL are refreshed. The selection of the word line WL is made by a refresh counter (not shown) included in the refresh control circuit 35.

The mode register set signal MRS is activated when the command signal CMD indicates a mode register set command. Accordingly, when the mode register set command is issued and a mode signal is supplied from the address terminals 21 in synchronism with this command, a set value of the mode register 14 can be overwritten.

A pair of clock terminals 23 is supplied with external clock signals CK and /CK from outside, respectively. These external clock signals CK and /CK are complementary to each other and then transferred to a clock input circuit 36. The clock input circuit 36 generates an internal clock signal ICLK based on the external clock signals CK and /CK. The internal clock signal ICLK is a basic clock signal within the semiconductor device 10. The internal clock signal ICLK is supplied to a timing generator 37 and thus various internal clock signals are generated. The various internal clock signals generated by the timing generator 37 are supplied to circuit blocks such as the address latch circuit 32 and the command decode circuit 34 and define operation timings of these circuit blocks.

The internal clock signal ICLK is also supplied to the DLL circuit 100 and a frequency detection circuit 40. The frequency detection circuit 40 is activated by DLL reset signal DLLRST and detects the frequency of the internal clock signal ICLK to generate frequency detection signal SEL. The configuration of the frequency detection circuit will be described later in detail. The frequency detection signal SEL is supplied to the DLL circuit 100.

The DLL circuit 100 generates the internal clock signal LCLK based on the internal clock signal ICLK. The internal clock signal LCLK is a clock signal that is phase-controlled. As explained above, the internal clock signal LCLK is supplied to the FIFO circuit 15 and the input/output circuit 16. In this manner, the read data DQ is output in synchronism with the internal clock signal LCLK. In the present Specification, the internal clock signal ICLK may be referred to as “the second clock signal”.

The DLL circuit 100 is reset by the DLL reset signal DLLRST output from the command decode circuit 34. The DLL reset signal DLLRST is activated in response to the reset signal /RESET or a DLL reset command (DLLRST). The reset signal /RESET is activated during an initializing sequence performed when a power supply is switched on. The DLL reset command is issued when the DLL circuit 100 needs to be reset. Accordingly, for example, immediately after a power supply is switched on, the DLL circuit 100 is reset by the DLL reset signal DLLRST.

The power supply terminals 25 are supplied with power supply potentials VDD and VSS. These power supply potentials VDD and VSS are supplied to an internal voltage generation circuit 38. The internal power supply generating circuit 38 generates various internal potentials VPP, VPERD, VPERI, and the like based on the power supply potentials VDD and VSS. The internal potential VPP is mainly used in the row decoder 12, the internal potential VPERD is mainly used in the DLL circuit 100, and the internal potential VPERI is used in many other circuit blocks.

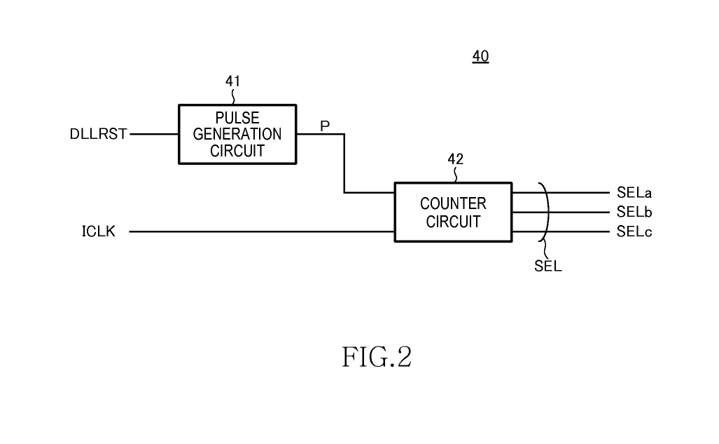

Turning to FIG. 2, the frequency detection circuit 40 includes a pulse generation circuit 41 and a counter circuit 42. In the present Specification, the counter circuit 42 may be referred to as “first circuit” and the pulse generation circuit 41 may be referred to as “second circuit”. The pulse generation circuit 41 is activated by a DLL reset signal DLLRST, which activates a pulse signal P for a predetermined period when the DLL reset signal DLLRST is input. The predetermined period has a specific length that does not depend on the frequency of the internal clock signal ICLK.

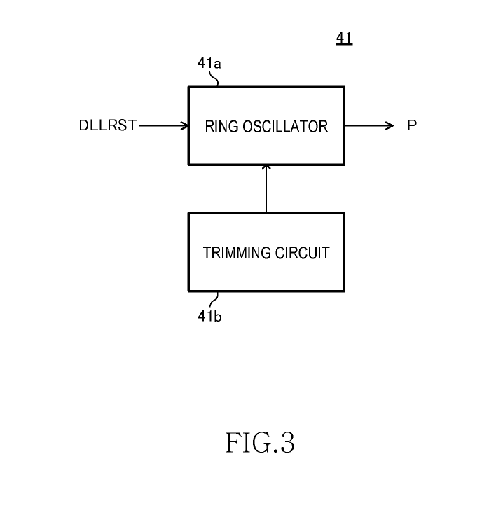

The specific circuit configuration of the pulse generation circuit 41 is not particularly limited, so long as the pulse generation circuit 41 is configured to generate the pulse signal P having a specific pulse width that does not depend on the frequency of the internal clock signal ICLK. For example, as shown in FIG. 3, the pulse generation circuit 41 can be configured to generate the pulse signal P by using a ring oscillator 41a. The ring oscillator 41a makes self oscillation, and therefore the ring oscillator 41a is configured to generate the pulse signal P having the specific pulse width that does not depend on the frequency of the internal clock signal ICLK. However, because there is a possibility that the characteristic of the ring oscillator 41a is changed from the design value due to a processing condition at the time of manufacturing, it is preferred to provide a trimming circuit 41b that adjusts the characteristic of the ring oscillator 41a. The pulse width of the pulse signal P output from the ring oscillator 41a is then measured at the stage of manufacturing, and when the measured pulse width is shifted from the design value, the characteristic of the ring oscillator 41a is adjusted by the trimming circuit 41b. With this operation, it is possible to set the pulse width of the pulse signal P to the design value regardless of the processing condition. The trimming circuit 41b can perform the trimming by using an irradiation of a laser beam or a circuit employing an anti-fuse element. It is not essential to configure the pulse generation circuit 41 with the ring oscillator 41a, but a general delay circuit can be also be used to configure the pulse generation circuit 41.

The counter circuit 42 counts the internal clock signal ICLK while the pulse signal P is activated. As described above, the pulse width of the pulse signal P is constant regardless of the frequency of the internal clock signal ICLK, and therefore the count value of the counter circuit 42 is determined by the frequency of the internal clock signal ICLK. Specifically, the count value is increased as the frequency of the internal clock signal ICLK is high, and on the contrary, the count value is decreased as the frequency of the internal clock signal ICLK is low. The counter circuit 42 then activates any one of frequency detection signals SELa to SELc based on the obtained count value. In the present embodiment, the obtained count value is compared with threshold values A and B (A is larger than B). If the obtained count value is equal to or larger than A, the counter circuit 42 activates the frequency detection signal SELa, if the obtained count value is equal to or larger than B and smaller than A, the counter circuit 42 activates the frequency detection signal SELb, and if the obtained count value is smaller than B, the counter circuit 42 activates the frequency detection signal SELc. This means that, if the frequency of the internal clock signal ICLK is higher than a first reference value f1, the counter circuit 42 activates the frequency detection value SELa, if the frequency of the internal clock signal ICLK is lower than a second reference value f2 (f2 is smaller than f1), the counter circuit 42 activates the frequency detection signal SELc, and if the frequency of the internal clock signal ICLK takes a value between the first reference value f1 and the second reference value f2, the counter circuit 42 activates the frequency detection signal SELb. The frequency detection signals SELa to SELc are signals constituting the frequency detection signal SEL shown in FIG. 1, which is supplied to the DLL circuit 100.

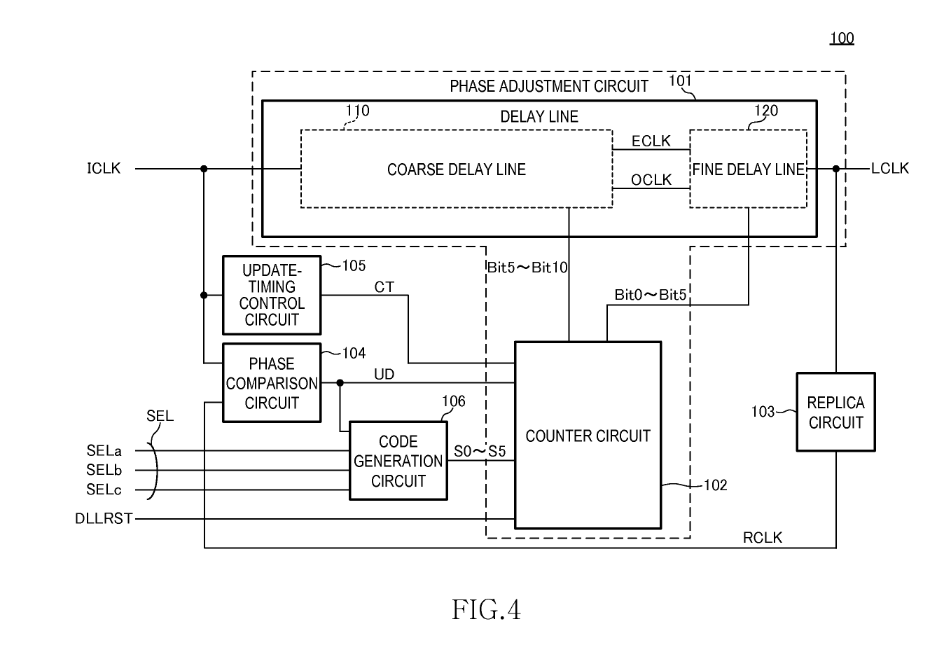

Turning to FIG. 4, the DLL circuit 100 includes a delay line 101 that generates the internal clock signal LCLK by delaying the internal clock signal ICLK. Although it is not particularly limited, the delay line 101 has a configuration in which a coarse delay line 110 having a relatively large delay-amount adjustment pitch and a fine delay line 120 having a relatively small delay-amount adjustment pitch are connected in series. The delay amount of the coarse delay line 110 is specified by upper bits Bit5 to Bit10 of a count value output from a counter circuit 102. Internal clock signals ECLK and OCLK output from the coarse delay line 110 are clock signals having different phases from each other by an amount of the minimum adjustment pitch of the coarse delay line 110.

On the other hand, the delay amount of the fine delay line 120 is specified by lower bits Bit0 to Bit5 of the count value output from the counter circuit 102. The internal clock signal LCLK is output from the fine delay line 120. The reason why the bit Bit5 of the count value is used for both the coarse delay line 110 and the fine delay line 120 is because the two internal clock signals ECLK and OCLK are output from the coarse delay line 110. That is, the bit Bit5 of the count value is used to determine phases of the internal clock signals ECLK and OCLK in the coarse delay line 110 and to determine which one of the phases of the internal clock signals ECLK and OCLK is advanced with respect to the other in the fine delay line 120.

The internal clock signal LCLK is supplied to the FIFO circuit 15 and the input/output circuit 16 shown in FIG. 1 and is also supplied to a replica circuit 103. The replica circuit 103 generates an internal clock signal RCLK as a replica signal based on the internal clock signal LCLK, and is configured to realize substantially the same delay amount as that realized by the FIFO circuit 15 and the output circuit 16a included in the input/output circuit 16. Because the output circuit 16a outputs the read data DQ synchronously with the internal clock signal LCLK as mentioned above, the internal clock signal RCLK output from the replica circuit 103 is accurately synchronized with the read data DQ. In a DRAM, the read data DQ needs to be accurately synchronized with the external clock signals CK and /CK and, when they have a difference in phases, such a phase difference needs to be detected and corrected. Detection is performed by a phase comparison circuit 104, and a result of the detection is fed back to the count circuit 102 to correct the phase difference.

The phase comparison circuit 104 compares phases of the internal clock signal ICLK with the internal clock signal RCLK and generates a phase determination signal PD based on a comparison result. Because the internal clock signal ICLK has substantially the same phase of the external clock signals CK and /CK and the internal clock signal RCLK has substantially the same phase of the read data DQ in this case, it implies that the phase comparison circuit 104 indirectly compares the phases of the external clock signals CK and /CK with the read data DQ. When a comparison result indicates that the internal cock signal RCLK is delayed from the internal clock signal ICLK, the count of the count circuit 102 is decreased based on the phase determination signal PD, thereby decreasing the delay amount of the delay line 101. Conversely, when the internal clock signal RCLK is ahead of the internal clock signal ICLK, the count of the count circuit 102 is increased based on the phase determination signal PD, thereby increasing the delay amount of the delay line 101. When the phases of the internal clock signal ICLK and the internal clock signal RCLK are matched by periodically repeating this operation, the phases of the read data DQ and the external clock signals CK and /CK are matched accordingly.

The update of the count value of the counter circuit 102 is performed in synchronization with an update signal CT output from an update-timing control circuit 105. The update-timing control circuit 105 generates the update signal CT by dividing the internal clock signal ICLK. Therefore, the count value of the counter circuit 102 is updated for each predetermined period of the internal clock signal ICLK. By periodically updating the count value of the counter circuit 102 in this manner, when phases of the internal clock signal ICLK and the reference clock signal RCLK are matched with each other, as a consequence, phases of the read data DQ and the external clock signals CK and /CK are matched with each other.

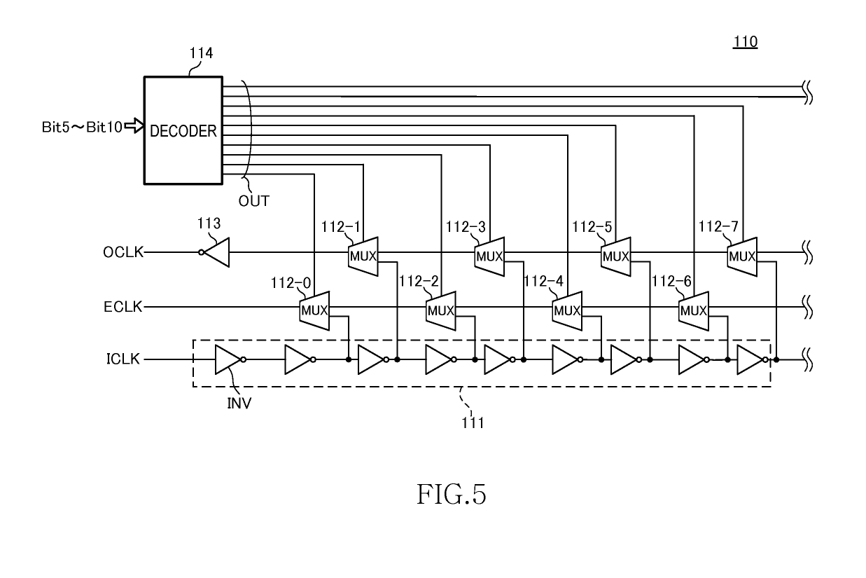

Turning to FIG. 5, the coarse delay line 110 includes an inverter chain 111 including a plurality of inverters INV connected in a cascaded manner and a plurality of multiplexers 112. Although only eight multiplexers 112-0 to 112-7 are shown in FIG. 5, more multiplexers 112 are provided in practice. Specifically, because the delay amount of the coarse delay line 110 is controlled by the bits Bit5 to Bit10 of the count value, the delay amount can be controlled by 64 steps (=2⁶), and therefore 65 multiplexers including multiplexers 112-0 to 112-64 are needed.

Each of the multiplexers 112 outputs either an output signal of the corresponding inverter INV or an output signal from a multiplexer 112 at the immediately previous stage. The selection of the output signal is performed based on an output signal OUT of a decoder 114. The decoder 114 decodes the bits Bit5 to Bit10 of the count value of the counter circuit 102, and two output signals OUT are activated from among a plurality of output signals OUT based on a result of the decoding.

The multiplexers 112 are divided into a first group for generating the internal clock signal ECLK and a second group for generating the internal clock signal OCLK, and the multiplexers 112 that belong to each group are connected in a cascaded manner. One multiplexer 112 is then selected for each of the first group and the second group based on the output signal OUT. The selected multiplexer 112 outputs the output signal of the corresponding inverter INV, and the other non-selected multiplexers 112 output the output signals from the respective multiplexers 112 at the immediately previous stages.

The multiplexer 112 based on the output signal OUT is selected in such a manner that the multiplexer 112 selected from the first group and the multiplexer 112 selected from the second group correspond to an input and an output of the same inverter INV. For example, when the multiplexer 112-1 is selected, the multiplexers 112-0 and 112-2 are also selected, and when the multiplexer 112-2 is selected, the multiplexer 112-1 or 112-3 is also selected. With this configuration, the phase difference between the obtained internal clock signals ECLK and OCLK becomes a delay amount of one stage of the inverter INV constituting the inverter chain 111. In this case, a delay by an inverter 113 for inverting the internal clock signal OCLK is ignored.

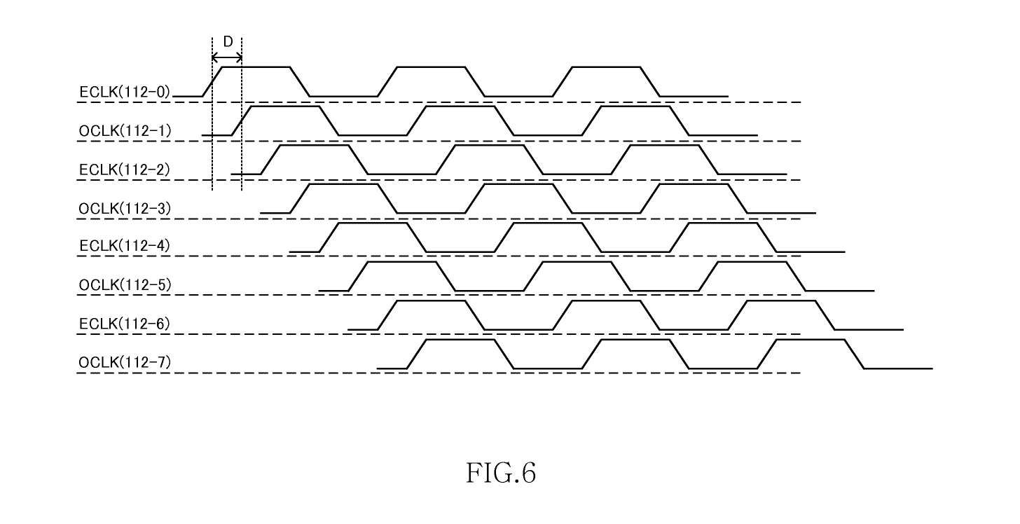

An operation of the coarse delay line 110 will be explained with reference to FIG. 6.

Although four waveforms for each of the internal clock signal ECLK and the internal clock signal OCLK are shown in FIG. 6, one waveform is output for each of the internal clock signals in practice. For example, when the multiplexers 112-0 and 112-1 shown in FIG. 5 are selected, the internal clock signal ECLK (112-0) and the internal clock signal OCLK (112-1) shown in FIG. 6 are output. As another example, when the multiplexers 112-1 and 112-2 are selected, the internal clock signal OCLK (112-1) and the internal clock signal LCLK (112-2) shown in FIG. 6 are output. As described above, a phase difference D between the internal clock signals ECLK and OCLK output from the coarse delay line 110 corresponds to the delay amount of one stage of the inverter constituting the inverter chain 111. The delay amount of one stage of the inverter corresponds to the minimum delay-amount adjustment pitch by the coarse delay line 110. The internal clock signals ECLK and OCLK generated in this manner are supplied to the fine delay line 120.

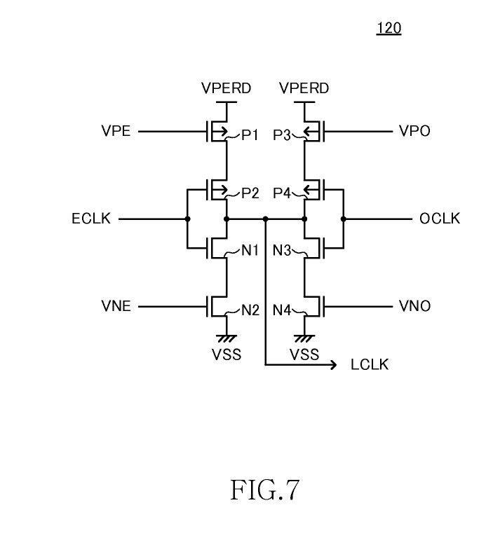

Turning to FIG. 7, the fine delay line 120 includes P-channel MOS transistors P1 and P2 and N-channel MOS transistors N1 and N2 connected in series between a first power source line to which a power source potential VPERD is supplied and a second power source line to which a power source potential VSS is supplied and P-channel MOS transistors P3 and P4 and N-channel MOS transistors N3 and N4 connected in series between a third power source line to which the power source potential VPERD is supplied and a fourth power source line to which the power source potential VSS is supplied. The internal clock signal ECLK is supplied to the gate electrodes of the transistors P2 and N1, and the internal clock signal OCLK is supplied to the gate electrodes of the transistors P4 and N3. The drains of the transistors P2, N1, P4, and N3 are commonly connected to a node, and the internal clock signal LCLK is output from the node.

On the other hand, bias voltages VPE, VNE, VPO, and VNO are supplied to the gate electrodes of the transistors P1, N2, P3, and N4, respectively. Levels of the bias voltages VPE, VNE, VPO, and VNO are controlled based on the bits Bit0 to Bit5 of the count value, by which the internal clock signals ECLK and OCLK are combined with a proportion according to the bits Bit0 to Bit5 of the count value. For example, when the levels of the bias voltages VPE and VNE are at a maximum select level and the levels of the bias voltages VPO and VNO are at a minimum select level, a source potential is not supplied to the transistors P4 and N3, and therefore the waveform of the obtained internal clock signal LCLK matches the internal clock signal ECLK. On the contrary, when the levels of the bias voltages VPE and VNE are at the minimum select level and the levels of the bias voltages VPO and VNO are at the maximum select level, a source potential is not supplied to the transistors P2 and N1, and therefore the waveform of the obtained internal clock signal LCLK matches the internal clock signal OCLK. When all the levels of the bias voltages VPE, VNE, VPO, and VNO are at an intermediate level, drain currents of the transistors P2 and N1 and drain currents of the transistors P4 and N3 substantially match each other, and therefore the waveform of the obtained internal clock signal LCLK becomes a waveform obtained by combining 50% of the internal clock signal ECLK and 50% of the internal clock signal OCLK. The proportion of combining the internal clock signals ECLK and OCLK can be adjusted in a plurality of steps based on the bits Bit0 to Bit5 of the count value.

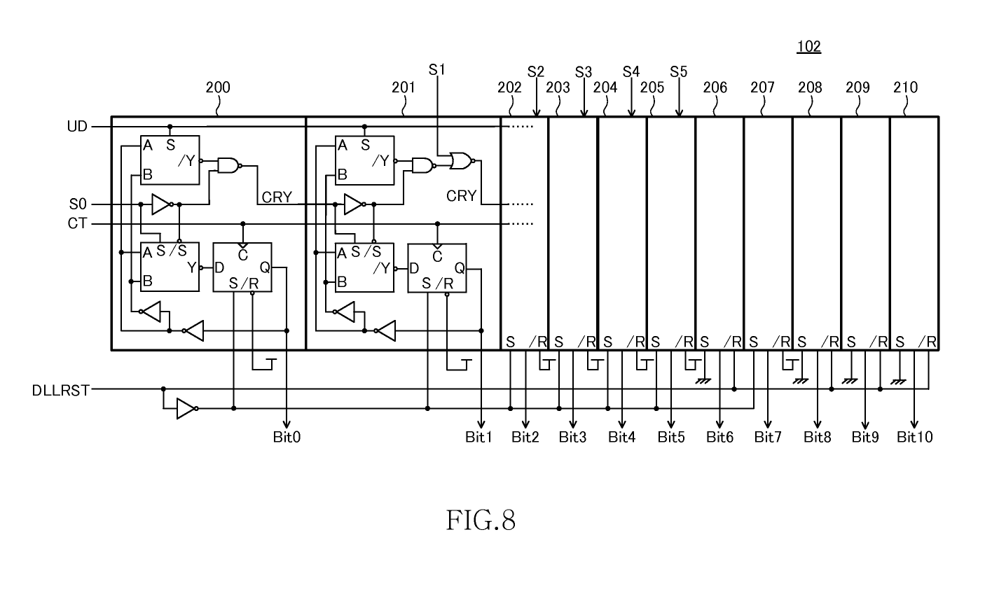

Turning to FIG. 8, the counter circuit 102 includes latch circuit units 200 to 210 respectively corresponding to the bits Bit0 to Bit10 of the count value. The bit Bit0 of the count value is the least significant bit (LSB), and the bit Bit10 of the count value is the most significant bit (MSB). A carry signal CRY output from a lower latch circuit unit is supplied to a higher latch circuit unit, and therefore the counter circuit 102 functions as an 11-bit binary counter. Counting up or counting down of the count value is performed based on a logical level of an up-down signal UD in synchronization with the update signal CT.

The counter circuit 102 used in the present embodiment can only the count up or count down from the least significant bit Bit0 as a normal counter circuit but also the count up or count down from an arbitrary bit. The bit from which the counting up or counting down is performed is specified by designation codes S0 to S5. The designation codes S0 to S5 are signals from which only one code becomes an activation level, which are generated by a code generation circuit 106 shown in FIG. 4.

Specific functions of the designation codes S0 to S5 are explained below. When the designation code S0 is activated, the up-down signal UD becomes valid with respect to the lowermost latch circuit unit 200. In this case, the counter circuit 102 counts up or counts down from the least significant bit Bit0 in the same manner as a normal counter circuit. This sets the delay-amount adjustment pitch to the minimum pitch. On the other hand, when the designation code S1 is activated, the bits Bit0 and Bit1 of the corresponding latch circuit unit 201 and the latch circuit unit 200 that is lower than the latch circuit unit 201 are fixed, and the up-down signal UD becomes valid with respect to the latch circuit unit 202 that is one stage upper than the latch circuit unit 201. In this case, the counter circuit 102 counts up or counts down from the bit Bit2, and therefore the value counted up or counted down at a time is 4 times the value counted up or counted down when the designation code S0 is activated. That is, the delay-amount adjustment pitch becomes 4 times the minimum pitch.

The operations when the designation codes S2 to S5 are activated are same with operations when the designation code S1 is activated. For example, when the designation code S4 is activated, the bits Bit0 to Bit4 of the corresponding latch circuit unit 204 and the latch circuit units 200 to 203 that are lower than the latch circuit unit 204 are fixed, and the up-down signal UD becomes valid with respect to the latch circuit unit 205 that is one stage upper than the latch circuit unit 204. In this case, the counter circuit 102 counts up or counts down from the bit Bit5, and therefore the value counted up or counted down at a time is 32 times the value counted up or counted down when the designation code S0 is activated. That is, the delay-amount adjustment pitch becomes 32 times the minimum pitch. With this configuration, the delay-amount adjustment pitch is selected from the minimum pitch and any one of pitches of 1 time, 4 times, 8 times, 16 times, 32 times, and 64 times the minimum pitch based on the designation codes S0 to S5.

One of the designation codes S0 to S5 by the code generation circuit 106 is activated based on the up-down signal UD and the frequency detection signal SEL. An operation of the code generation circuit 106 is explained below in detail.

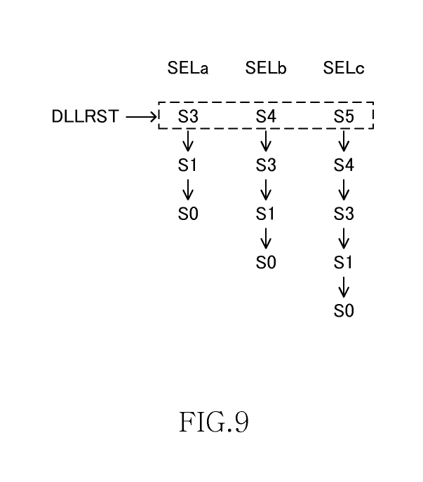

First, when the DLL reset signal DLLRST is activated, the code generation circuit 106 activates any one of the designation codes S3 to S5 based on the frequency detection signal SELa to SELc. Specifically, as shown in FIG. 9, the code generation circuit 106 activates the designation code S3 when the frequency detection signal SELa is activated, activates the designation code S4 when the frequency detection signal SELb is activated, and activates the designation code S5 when the frequency detection signal SELc is activated. With this operation, when the frequency of the internal clock signal ICLK is higher than the first reference value f1, the counter circuit 102 counts up or counts down from the bit Bit4, and therefore the delay-amount adjustment pitch becomes 16 times the minimum pitch. On the other hand, when the frequency of the internal clock signal ICLK is between the first reference value f1 and the second reference value f2, the counter circuit 102 counts up or counts down from the bit Bit5, and therefore the delay-amount adjustment pitch becomes 32 times the minimum pitch. In addition, when the frequency of the internal clock signal ICLK is lower than the reference value f2, the counter circuit 102 counts up or counts down from the bit Bit6, and therefore the delay-amount adjustment pitch becomes 64 times the minimum pitch.

In this manner, immediately after the DLL reset signal DLLRST is activated, the bit to be counted up or counted down is selected based on the frequency of the internal clock signal ICLK. When the frequency of the internal clock signal ICLK is high, if the delay-amount adjustment pitch is to large, an edge of the reference clock signal RCLK may be far beyond a target edge, and in this case, it may not be possible to perform a phase adjustment operation correctly. However, in the present embodiment, when the frequency of the internal clock signal ICLK is high, the delay-amount adjustment pitch is set to a small value, and as a result, there occurs no such problem. On the other hand, when the frequency of the internal clock signal ICLK is low, if the delay-amount adjustment pitch is too small, it takes a long time for the edge of the reference clock signal RCLK to reach the target edge. However, in the present embodiment, when the frequency of the internal clock signal ICLK is low, the delay-amount adjustment pitch is set to a large value, and as a result, there occurs no such problem.

When such a phase adjustment operation is continued, the edge of the reference clock signal RCLK approaches the target edge. When the edge of the reference clock signal RCLK exceeds the target edge, the logical level of the up-down signal UD is inverted. Therefore, by monitoring a change of the logical level of the up-down signal UD, it is possible to find out whether the edge of the reference clock signal RCLK has approached the target value. The monitoring of the logical level of the up-down signal UD is performed by the code generation circuit 106 shown in FIG. 4. In the present embodiment, when the logical level of the up-down signal UD is inverted once or twice, the phase adjustment operation using the designation code is completed, and the process control is switched to a lower bit. This means that the logical level of the corresponding bit is fixed.

Specifically, as shown in FIG. 9, if the phase adjustment operation is completed by using the designation code S3 when the frequency detection signal SELa is activated, the final count value is obtained by sequentially activating the designation codes S1 and S0. Furthermore, if the phase adjustment operation is completed by using the designation code S4 when the frequency detection signal SELb is activated, the final count value is obtained by sequentially activating the designation codes S3, S1, and S0. In addition, if the phase adjustment operation is completed by using the designation code S5 when the frequency detection signal SELc is activated, the final count value is obtained by sequentially activating the designation codes S4, S3, S1, and S0. In any case, the designation code S2 is not used; however, it is needless to mention that the designation code S2 can be also used. In the case of using the designation code S2, the designation code S2 can be used after the designation code S3.

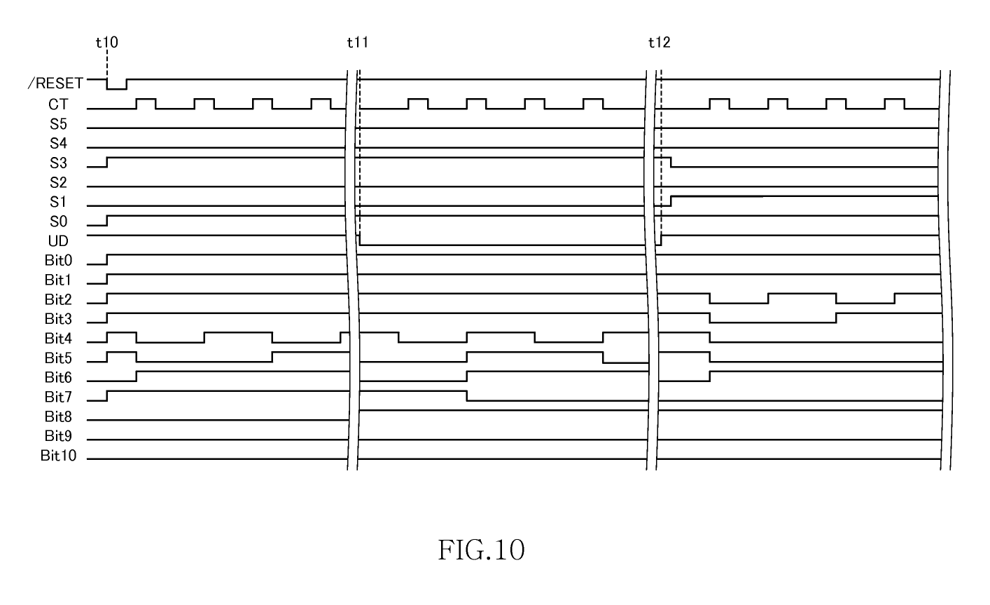

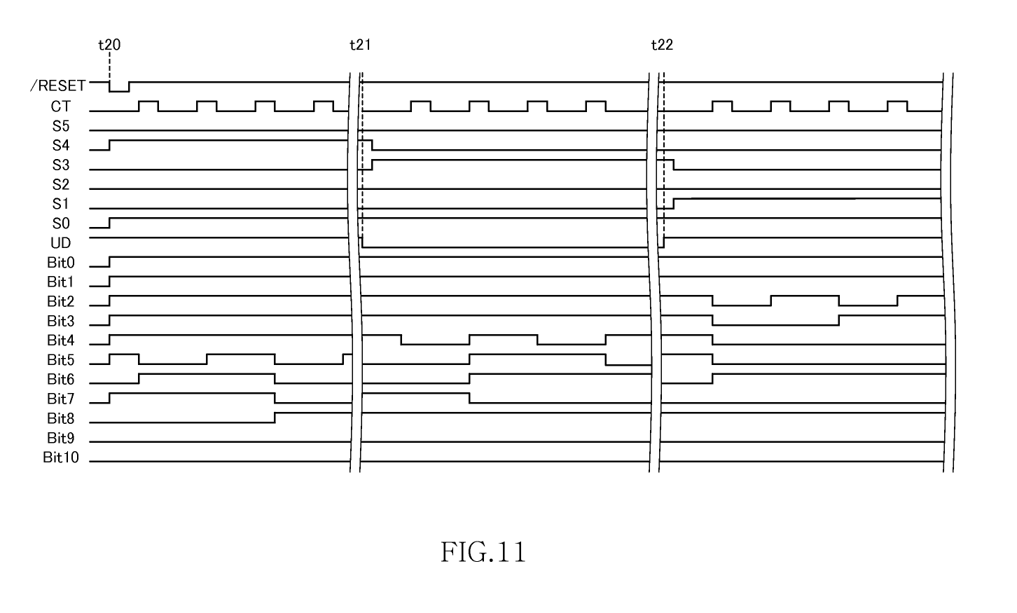

An operation of the DLL circuit 100 will be explained with reference to FIGS. 10 and 11.

Because the frequency detection signal SELa is activated in the example shown in FIG. 10, when the reset signal /RESET is issued at a time t10, the designation code S3 is activated to a high level. Although the designation code S0 is also at a high level, the designation code S0 is an active-low signal. With this operation, the counter circuit 102 counts up or counts down from the bit Bit4 based on the up-down signal UD every time the update signal CT is activated. It can be said that it is a state where the counter circuit 102 functions as a 7-bit counter circuit including the bits Bit4 to Bit10 with the bit Bit4 as the least significant bit (LSB). The higher bits Bit0 to Bit3 maintain their initial values. In the example shown in FIG. 10, the initial values of the bits Bit0 to Bit3 are all at a high level.

In a period from the time t10 to a time t11, because the up-down signal UD is at a high level, the counter circuit 102 counts up from the bit Bit4. With this operation, the delay-amount is adjusted with the delay-amount adjustment pitch of 16 times the minimum pitch. In the example shown in FIG. 10, the up-down signal UD is inverted from a high level to a low level at the time t11. With this operation, the counter circuit 102 counts down from the bit Bit4.

Thereafter, at a time t12, the up-down signal UD is inverted from a low level to a high level. In response to this second inversion, the code generation circuit 106 activates the designation code S1 instead of the designation code S3. With this operation, the counter circuit 102 counts up or counts down from the bit Bit2 based on the up-down signal UD every time the update signal CT is activated. It can be said that it is a state where the counter circuit 102 functions as a 9-bit counter circuit including the bits Bit2 to Bit10 with the bit Bit2 as the least significant bit (LSB). With this operation, the delay-amount is adjusted with the delay-amount adjustment pitch of 4 times the minimum pitch.

Although subsequent operations are not shown in the drawings, when the up-down signal UD is further inverted, the code generation circuit 106 activates the designation code S0 instead of the designation code S1. With this operation, the counter circuit 102 counts up or counts down from the bit Bit0 based on the up-down signal UD every time the update signal CT is activated. In this state, the counter circuit 102 functions as an 11-bit counter circuit including the bits Bit0 to Bit10 with the bit Bit0 as the least significant bit (LSB), and the delay-amount adjustment pitch becomes the minimum pitch. With this operation, the count value of the 11-bit counter circuit 102 is fixed.

Because the frequency detection signal SELb is activated in the example shown in FIG. 11, when the reset signal /RESET is issued at a time t20, the designation code S4 is activated to a high level. With this operation, the counter circuit 102 counts up or counts down from the bit Bit5 based on the up-down signal UD every time the update signal CT is activated. It can be said that it is a state where the counter circuit 102 functions as a 6-bit counter circuit including the bits Bit5 to Bit10 with the bit Bit5 as the least significant bit (LSB). The higher bits Bit0 to Bit4 maintain their initial values.

In a period from the time t20 to a time t21, because the up-down signal UD is at a high level, the counter circuit 102 counts up from the bit Bit5. With this operation, the delay-amount is adjusted with the delay-amount adjustment pitch of 32 times the minimum pitch.

Thereafter, at the time t21, the up-down signal UD is inverted from a high level to a low level. In response to this inversion, the code generation circuit 106 activates the designation code S3 instead of the designation code S4. With this operation, the counter circuit 102 counts up or counts down from the bit Bit4 based on the up-down signal UD every time the update signal CT is activated. Subsequent operations are identical to those explained with reference to FIG. 10, so that, by switching the designation code every time the up-down signal UD is inverted, the count value of the 11-bit counter circuit 102 is fixed.

Although an operation of the DLL circuit 100 in the case where the frequency detection signal SELc is activated is not shown in the drawings, also in this operation, the count value of the 11-bit counter circuit 102 is fixed by sequentially activating the designation codes from the designation code S5.

In this manner, according to the present embodiment, because the delay-amount adjustment pitch of the delay line 101 is switched based on the frequency of the internal clock signal ICLK, it is possible to perform the phase control operation appropriately corresponding to the frequency. This makes it possible to adjust phase correctly without missing the target edge when the frequency of the internal clock signal ICLK is high and to complete the phase control operation quickly when the frequency of the internal clock signal ICLK is low.

It is apparent that the present invention is not limited to the above embodiments, but may be modified and changed without departing from the scope and spirit of the invention.

For example, a case where the present invention is applied to the DRAM has been explained in the above embodiment as an example. However, the application range of the present invention is not limited to the DRAM. That is, the present invention can be applied to other types of semiconductor memory devices (such as a flash memory and a ReRAM), and can be further applied to a logic-based semiconductor device such as a processor. In addition, it is not essential to integrate all the constituent elements of the semiconductor device according to the present invention in a single semiconductor chip. That is, the constituent elements of the present invention can be configured with a plurality of semiconductor chips.

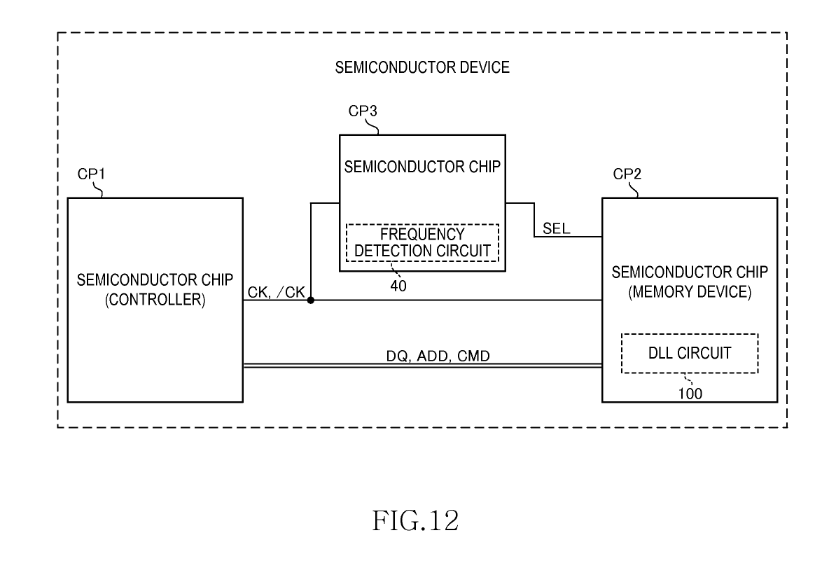

FIG. 12 is a block diagram showing an example of distributing the constituent elements of the semiconductor device according to the present invention to a plurality of semiconductor chips. The semiconductor device shown in FIG. 12 includes a semiconductor chip CP1 as a controller, a semiconductor chip CP2 as a memory device, and a semiconductor chip CP3 that includes the frequency detection circuit 40. The semiconductor chip CP1 is a control device that supplies the address signal ADD, the command signal CMD, and the external clock signals CK and /CK to the semiconductor chip CP2 and performs transmission and reception of the data DQ. The semiconductor chip CP2 is a memory device of which the operation is controlled by the semiconductor chip CP1. In this example, the semiconductor chip CP2 includes the DLL circuit 100, but does not include the frequency detection circuit 40. The frequency detection circuit 40 is integrated in the separate semiconductor chip CP3, so that the frequency detection signal SEL generated by the semiconductor chip CP3 is supplied to the semiconductor chip CP1. In this manner, in the present invention, the frequency detection circuit 40 can be integrated in a separate semiconductor chip.

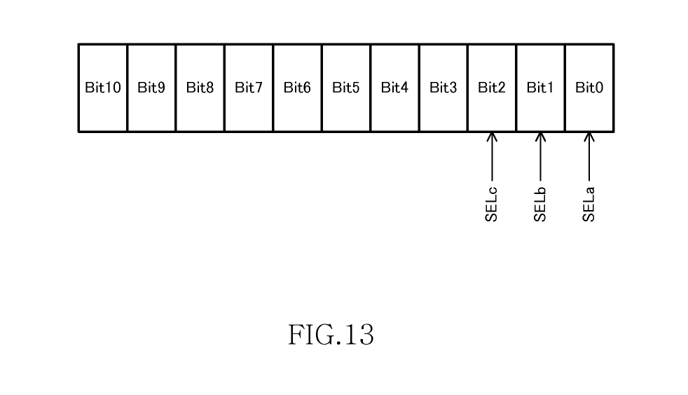

Furthermore, in the above embodiment, the count value is generated by a so-called “binary search” in which the logical levels are sequentially fixed from the upper bit of the counter circuit 102; however, this feature is not essential in the present invention. For example, the number of effective bits of the counter circuit 102 can be changed based on the frequency of the internal clock signal ICLK. In the example shown in FIG. 13, the count value is used with the bit Bit0 as the least significant bit (LSB) when the frequency detection signal SELa is activate (the frequency is high), the bit Bit1 as the least significant bit (LSB) ignoring the bit Bit0 when the frequency detection signal SELb is activated (the frequency is intermediate), and the bit Bit2 as the least significant bit (LSB) ignoring the bits Bit0 and Bit1 when the frequency detection signal SELc is activated (the frequency is low). In any case, the counting up or counting down is performed from the selected least significant bit. The bit to be counted up or counted down is not changed in the same manner as the above embodiment. With this method, a highly-accurate phase control operation can be performed when the frequency of the internal clock signal ICLK is high while the phase control operation can be performed quickly when the frequency of the internal clock signal ICLK is low. Although the accuracy of the phase control operation is degraded when the frequency of the internal clock signal ICLK is low because the bits Bit0 and Bit1 are ignored, this does not cause any significant problem when the frequency of the internal clock signal ICLK is low. As another example, a range of operating the counter circuit 102 can be changed based on the frequency of the internal clock signal ICLK.

Further, in the above embodiment, the operation mode of the DLL circuit 100 is selected from three different operation modes based on the frequency of the internal clock signal ICLK; however, the type of the operation mode is not limited to the three types. That is, the type of the operation mode can be two types or 4 types or more. In addition, although the frequency of the internal clock signal ICLK is detected by the frequency detection circuit 40 in the above embodiment, the actually monitored clock signal is not limited to the internal clock signal ICLK. That is, the frequency of the internal clock signal ICLK can be directly monitored, and the frequency of the internal clock signal LCLK can be monitored instead.

Further, in the above embodiment, a DLL circuit has been explained as an example of the clock generation circuit; however, it is not essential that the clock generation circuit as a control target in the present invention is the DLL circuit, and other types of clock generation circuit can be applicable. For example, in the above embodiment, although the internal clock signal LCLK is generated by delaying the internal clock signal ICLK, the clock generation method is not limited to any particular method so long as another clock signal is generated by receiving a predetermined clock signal and shifting the phase of the received clock signal.

What is claimed is:

1. A semiconductor device comprising:
a frequency detection circuit outputting a frequency detection signal based on a frequency of a first clock signal;
a phase comparison circuit comparing a phase of the first clock signal with a phase of a reference clock signal to generate a phase comparison signal; and
a phase adjustment circuit outputting a second clock signal by shifting the phase of the first clock signal based on the phase comparison signal, an amount of shifting the phase of the first clock signal being variable according to the frequency detection signal.

2. The semiconductor device as claimed in claim 1, wherein the frequency detection circuit includes a first circuit that counts one of the first and second clock signals for a predetermined period, and outputs the frequency detection signal based on a count value thereof.

3. The semiconductor device as claimed in claim 2, wherein the frequency detection circuit further includes a second circuit that defines the predetermined period, the second circuit being activated at a time of an initial operation of the semiconductor device.

4. The semiconductor device as claimed in claim 3, wherein the second circuit includes a trimming circuit that adjusts the predetermined period.

5. The semiconductor device as claimed in claim 1, wherein
the phase adjustment circuit includes a counter circuit that updates a count value thereof based on the phase comparison signal, and a delay line that generates the second clock signal by delaying the first clock signal based on the count value of the counter circuit, and
an update pitch of the count value of the counter circuit is variable based on the frequency detection signal.

6. The semiconductor device as claimed in claim 5, wherein the counter circuit updates the count value with a first pitch based on the frequency detection signal, and then updates the count value with a second pitch that is smaller than the first pitch based on the phase comparison signal.

7. The semiconductor device as claimed in claim 6, wherein the counter circuit updates the count value with the second pitch based on a first change of the phase comparison signal, and then updates the count value with a third pitch that is smaller than the second pitch based on a second change of the phase comparison signal.

8. The semiconductor device as claimed in claim 5, wherein
the delay line includes a coarse delay line having a relatively large adjustment pitch and a fine delay line having relatively small adjustment pitch,
the coarse delay line is controlled by upper bits of the count value of the counter circuit, and
the fine delay line is controlled by lower bits of the count value of the counter circuit.

9. The semiconductor device as claimed in claim 1, wherein the frequency detection circuit, the phase comparison circuit and the phase adjustment circuit are integrated in the same semiconductor chip.

10. The semiconductor device as claimed in claim 1, wherein the frequency detection circuit is integrated in a different semiconductor chip in which the phase comparison circuit and the phase adjustment circuit are integrated.

11. A method of adjusting a phase of a clock signal, the method comprising:
detecting a frequency of a first clock signal or a second clock signal;
generating the second clock signal based on the first clock signal by performing a plurality of phase adjusting operations; and
changing a phase adjustment pitch in each of the phase adjusting operations based on the detected frequency.

12. The method of adjusting a phase of a clock signal as claimed in claim 11, wherein the detecting is performed by counting the first clock signal or the second clock signal for a predetermined period to obtain a first count value, and the frequency is detected based on the first count value.

13. The method of adjusting a phase of a clock signal as claimed in claim 12, further comprising trimming to adjust the predetermined period.

14. The method of adjusting a phase of a clock signal as claimed in claim 11, wherein
each of the phase adjusting operations is performed by updating a second count value indicative of a phase difference between the first clock signal and the second clock signal, and
the phase adjustment pitch is changed by switching a target bit to be updated in the second count value according to the detected frequency.

15. A semiconductor device comprising:
a delay circuit configured to receive a first clock signal to generate a second clock signal;
a detection circuit configured to detect a frequency of the first clock signal to generate a detection signal; and
a control circuit configured to be supplied with the detection signal, to control the delay circuit to shift one of rising and falling edges of the first clock signal at first intervals when the detection signal takes a first value, and to control the delay circuit to shift the one of rising and falling edges of the first clock signal at second intervals when the detection signal takes a second value different from the first value, the first intervals being different from the second intervals.

16. The semiconductor device as claimed in claim 15, wherein the detection circuit includes a counter circuit configured to count a number of clocking of the first clock signal during a first period, the first period being determined independently of the frequency of the first clock signal.

17. The semiconductor device as claimed in claim 16, wherein the detection circuit includes a pulse generation circuit generating a pulse signal and a width of the pulse signal is defined as the first period.

18. The semiconductor device as claimed in claim 17, wherein the pulse generation circuit includes a ring oscillator circuit generating an internal clock signal irrespective of the first clock signal and the pulse signal is generated in response to the internal clock signal.

19. The semiconductor device as claimed in claim 18, wherein the width of the pulse signal is substantially equal to an integral multiple of a clock cycle period of the internal clock signal.

20. The semiconductor device as claimed in claim 15, wherein the detection signal takes the first value when the detection circuit detects that the frequency is a first frequency and the second value when the detection circuit detects that the frequency is a second frequency greater than the first frequency, the first intervals being greater than the second intervals.
